(19) United States
(12) Patent Application Publication
(10) Pub. No.: US 2026/0147284 A1
(43) Pub. Date: May 28, 2026

(54) EXPOSURE APPARATUS AND ARTICLE MANUFACTURING METHOD

(71) Applicant: CANON KABUSHIKI KAISHA, Tokyo (JP)

(72) Inventor: MASATO HOMMA, Tochigi (JP)

(21) Appl. No.: 19/394,649

(22) Filed: Nov. 19, 2025

(30) Foreign Application Priority Data
Nov. 27, 2024 (JP) 2024-206580
Nov. 27, 2024 (JP) 2024-206581

(51) Int. Cl. G03F 7/00; F24F 11/74

(52) U.S. Cl. CPC G03F 7/70925; F24F 11/74; G03F 7/70525; G03F 7/70716; G03F 7/70775; G03F 7/7085; G03F 7/70858; G03F 7/70933

(57) ABSTRACT

An exposure apparatus that exposes a substrate to light is provided. The apparatus includes a projection optical system configured to project a pattern image of an original plate onto the substrate, a supply unit configured to supply a gas to a space between the projection optical system and the substrate, a measurement unit configured to measure a position of the substrate, and a controller configured to control supply of the gas by the supply unit so as to change a flow velocity of the gas passing between the measurement unit and the substrate.

### BACKGROUND

### Field of the Technology

The present disclosure relates to an exposure apparatus and an article manufacturing method.

### Description of the Related Art

As one of the apparatuses used in a lithography step during the manufacture of a liquid crystal panel or a semiconductor device, an exposure apparatus is available which projects the pattern of an original plate illuminated by an illumination optical system onto a substrate and exposes the substrate to light. A substrate (wafer) used in the exposure apparatus is coated with a resist, which can produce contaminants when exposed to light. Such contaminants fog optical elements when they react with impurities such as acids, bases, or organics in an ambient atmosphere or in the films of the optical elements around a wafer. In particular, the optical element placed at the lowermost end of a projection optical system is prone to a fogging phenomenon because it is placed immediately above a wafer.

Contaminants that fog the optical element placed at the lowermost end of a projection optical system do not originate from only a resist. There is a driving system or structure using grease or adhesive that is also likely to generate contaminants around the projection optical system, and a component itself uses a resin or rubber that is likely to generate contaminants. The contaminants originating from them are carried by air conditioning to around a wafer and reach the optical element placed at the lowermost end of the projection optical system, thus fogging the optical element.

The fogging of an optical element can cause underexposure, illuminance unevenness, flare, and the like, resulting in a deterioration in the transfer accuracy of an original plate pattern onto a wafer. For this reason, an air nozzle can be placed near the optical element of the exposure apparatus to blow away contaminants. In a case where contaminants are blown away by the air nozzle, it is generally advantageous to flow a gas at a high flow velocity and a high flow rate between the entire wafer and optical element. As such a gas, for example, clean air, clean dry air, or nitrogen gas is used.

Japanese Patent Laid-Open No. 2022-011815 discloses a method of flowing a gas at a substantially higher flow rate than the supply flow rate between a wafer and an optical element. More specifically, Japanese Patent Laid-Open No. 2022-011815 discloses that a gas supply port is provided near a projection optical system, and a wind deflector is placed so as to guide the gas blown out from the gas supply port to between the wafer and the optical element. This wind deflector convolutes a gas from a clean portion, straightens the flow of the gas, and guides the gas between the wafer and the optical element, thereby flowing the gas at a high flow velocity and a high flow rate.

Japanese Patent Laid-Open No. 2023-148841 discloses a technique of regulating the flow rate of a gas in accordance with the distribution of the fogging of an optical element to flow the gas at a maximum flow rate within a possible range because simply flowing a gas at a high flow velocity and a high flow rate between the wafer and the optical element sometimes unintentionally convolutes contaminants.

Simply flowing a gas at a high flow velocity and a high flow rate to protect the optical element from contaminants will also flow the gas at a high flow velocity and a high flow rate to a measurement system located downstream of the optical element. This can cause air fluctuation in a measurement system optical path, thus leading to a deterioration in measurement accuracy. In addition, the collision of a high-flow velocity gas against a measurement system structure can cause the structure itself to finely vibrate and further degrade the measurement accuracy.

### SUMMARY

The present disclosure provides a technique advantageous in satisfying requirements for both the fogging prevention performance of the optical element of a projection optical system and the measurement accuracy of a substrate position.

The present disclosure in one aspect provides an exposure apparatus that exposes a substrate to light, the apparatus including a projection optical system configured to project a pattern image of an original plate onto the substrate, a supply unit configured to supply a gas to a space between the projection optical system and the substrate, a measurement unit configured to measure a position of the substrate, and a controller configured to control supply of the gas by the supply unit so as to change a flow velocity of the gas passing between the measurement unit and the substrate.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic diagram illustrating a view of an arrangement of an exposure apparatus according to a first embodiment.

FIG. 2 is a schematic diagram illustrating a view of an arrangement of the exposure apparatus without any baffle plate according to the first embodiment.

FIG. 3 is a schematic diagram illustrating a view for explaining the size of a gas supply unit according to the first embodiment.

FIGS. 4A and 4B are schematic diagrams illustrating views for explaining the control of a substrate stage in an exposure sequence according to the first embodiment.

FIG. 5 is a schematic diagram illustrating a view of an arrangement of the exposure apparatus including a temperature sensor according to the first embodiment.

FIG. 6 is a schematic diagram illustrating a view of an arrangement of the exposure apparatus including an exhaust unit and an exhaust flow rate regulator according to a second embodiment.

FIGS. 7A and 7B are schematic diagrams illustrating views for explaining the placement position of the exhaust unit according to the second embodiment.

FIG. 8 is a schematic diagram illustrating a view of an arrangement of the exposure apparatus including a plurality of flow rate regulators according to a third embodiment.

FIG. 9 is a schematic diagram illustrating a view of an arrangement of the exposure apparatus including a plurality of flow rate regulators according to the third embodiment.

FIG. 10 is a schematic diagram illustrating a view of an overall arrangement of the exposure apparatus according to a fourth embodiment.

FIG. 11 is a schematic diagram illustrating a view of an arrangement of the exposure apparatus according to a fifth embodiment.

FIG. 12 is a schematic diagram illustrating a view of an arrangement of a detection unit according to the fifth embodiment.

FIG. 13 is a schematic diagram illustrating a view for explaining the size of the gas supply unit according to the fifth embodiment.

FIGS. 14A to 14C are schematic diagrams illustrating views for explaining the control of the substrate stage in an exposure sequence according to the fifth embodiment.

FIGS. 15A and 15B are timing charts of the flow rate regulation of a first gas.

FIG. 16 is a schematic diagram illustrating a view of an arrangement of the exposure apparatus including the temperature sensor according to the fifth embodiment.

FIG. 17 is a schematic diagram illustrating a view of an arrangement of the exposure apparatus including the temperature sensor and a plurality of flow rate regulators according to the fifth embodiment.

FIG. 18A is a schematic diagram illustrating a view for explaining the flow rate regulation of a gas using a plurality of flow rate regulators according to a sixth embodiment.

FIG. 18B is a schematic diagram illustrating a view for explaining the flow rate regulation of a gas using the plurality of flow rate regulators according to the sixth embodiment.

FIG. 18C is a schematic diagram illustrating a view for explaining the flow rate regulation of a gas using the plurality of flow rate regulators according to the sixth embodiment.

FIG. 19 is a schematic diagram illustrating a view of an overall arrangement of the exposure apparatus according to a seventh embodiment.

### DESCRIPTION OF THE EMBODIMENTS

Hereinafter, embodiments will be described in detail with reference to the attached drawings. The following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

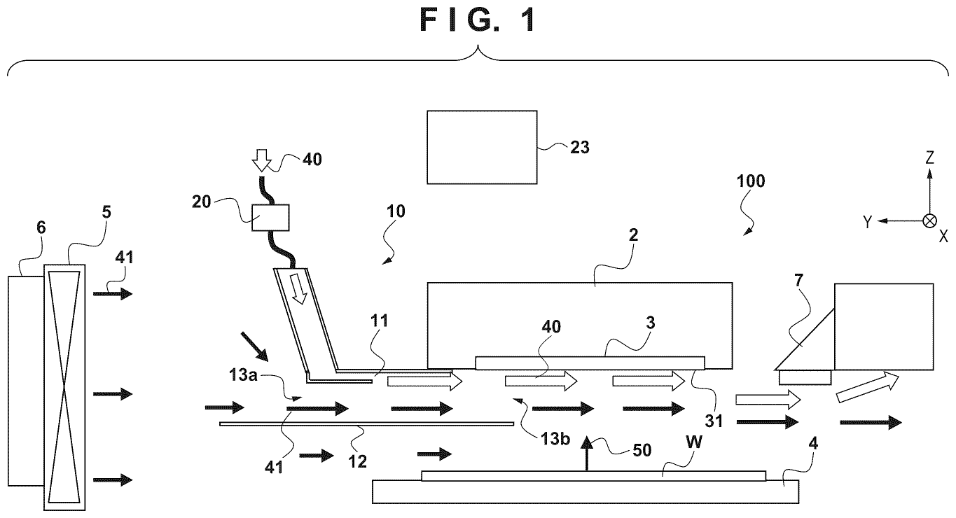

FIG. 1 is a schematic diagram illustrating a view of an exposure apparatus 100 according to a first embodiment. In the present specification and the accompanying drawings, directions will be indicated in an XYZ coordinate system in which a horizontal plane is an X-Y plane. In general, a substrate W as an exposure target is placed on a substrate stage 4 such that the surface of the substrate W becomes parallel to a horizontal plane (X-Y plane). Accordingly, in the following description, directions orthogonal to each other within a plane along the surface of the substrate W are respectively defined as the X-axis and the Y-axis, and a direction perpendicular to the X-axis and the Y-axis is defined as the Z-axis. In the following description, directions parallel to the X-axis, the Y-axis, and the Z-axis in the XYZ coordinate system are respectively defined as the X direction, the Y direction, and the Z direction.

### First Embodiment

Referring to FIG. 1, the exposure apparatus 100 can include a projection optical system 2, a substrate stage 4, a measurement unit 7, and a controller 23. The projection optical system 2 can include an optical element 3 placed at the lowermost end of the projection optical system 2. The exposure apparatus 100 can further include a gas supply unit 10 (supply unit). The gas supply unit 10 supplies a first gas 40 to the space between the projection optical system 2 (the optical element 3 thereof) and a substrate W (wafer) held by the substrate stage 4. The gas supply unit 10 can include a gas supply port 11 and a flow rate regulator 20 that regulates the supply flow rate of the first gas 40 flowing from the gas supply port 11. The gas supply unit 10 may be fixed to the projection optical system 2 or fixed to a base portion (not shown) near the projection optical system 2.

The measurement unit 7 is configured to emit measurement light to the substrate stage 4 and measure the position of the substrate stage 4 or the substrate W. The measurement unit 7 can be, for example, an off-axis alignment scope (OAS) for measuring a mark on a substrate. In order to improve the measurement accuracy of the measurement unit 7, there is a need to maintain constant temperature, pressure, and humidity of an atmosphere through which measurement light passes. The measurement unit 7 is placed at any position where the first gas 40 flows. Referring to FIG. 1, the measurement unit 7 is placed downstream of the projection optical system 2 with respect to the airflow of the first gas 40. However, the measurement unit 7 may be placed upstream of the projection optical system 2.

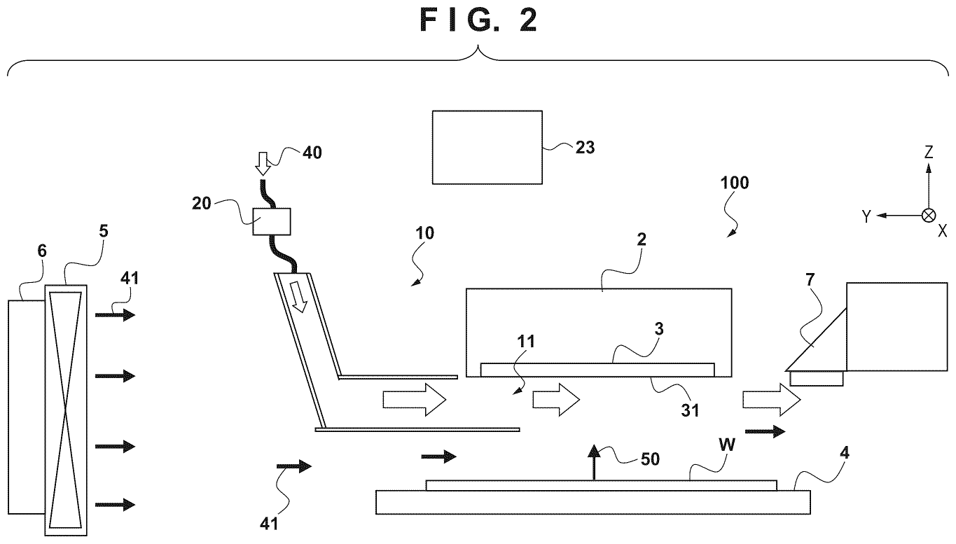

The gas supply unit 10 can further include a baffle plate 12. A first opening portion 13a is formed by a partition of the gas supply port 11 and the baffle plate 12 at a position away from the exposure center. A second opening portion 13b is formed by the projection optical system 2 and the baffle plate 12 at a position close to the exposure center. Although the baffle plate 12 is used to regulate an airflow around the gas supply unit 10 in a predetermined direction, prevent the convolution of a surrounding gas, or regulate the convoluting direction of the surrounding gas, the baffle plate 12 is not essential. As an example of the exposure apparatus 100 without the baffle plate 12, the lower wall of the gas supply port 11 of the gas supply unit 10 may be extended into the space between the optical element 3 and the substrate stage 4 so as to function as a baffle plate, as shown in FIG. 2. Referring to FIGS. 1 and 2, although the gas supply port 11 is placed to be positioned below the projection optical system 2, the gas supply port 11 may be placed elsewhere relative to the projection optical system 2 and configured to supply the first gas 40 from the placed position to the space between the optical element 3 and the substrate stage 4.

The controller 23 is configured by a computer including, for example, a CPU (processor) and a memory. The controller 23 is electrically connected to each unit in the apparatus to comprehensively control each unit. Note that the controller 23 may be implemented as a server apparatus that is installed in a place different from a room (for example, a clean room) where the exposure apparatus 100 is installed and connected to the exposure apparatus 100 via a wired or wireless network.

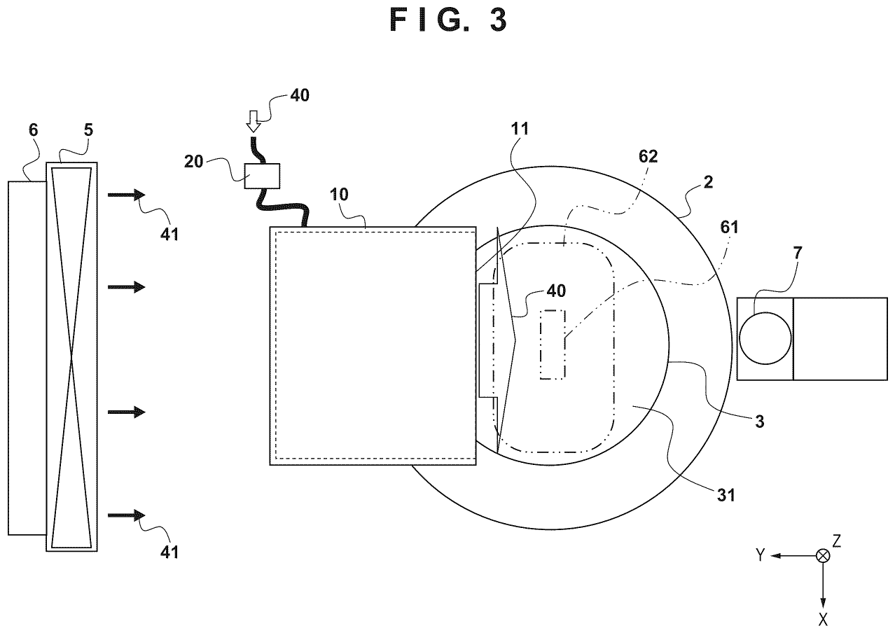

FIG. 3 illustrates a view of the gas supply unit 10 from below the projection optical system 2 (although the baffle plate 12 is not shown). As shown in FIG. 3, the size of the gas supply port 11 in a direction (X direction) perpendicular to the blowing direction (Y direction) of the first gas 40 through the gas supply port 11 is preferably larger than an irradiation range 61 that is a range in which the substrate W is irradiated with laser light passing through the projection optical system 2. Furthermore, the size is preferably larger than a range 62 in which laser light passes through a first surface 31 of the optical element 3, which is located on the side of the optical element 3 facing the substrate W.

The first gas 40 is preferably a clean gas so as not to adversely affect the fogging of the optical element 3. A clean gas means a gas with few impurities such as acids, bases, or organics. This gas is further preferably a gas such as an inert gas like nitrogen gas obtained by drying clean air (clean dry air) obtained by removing impurities such as acids, bases, or organics from air (clean air).

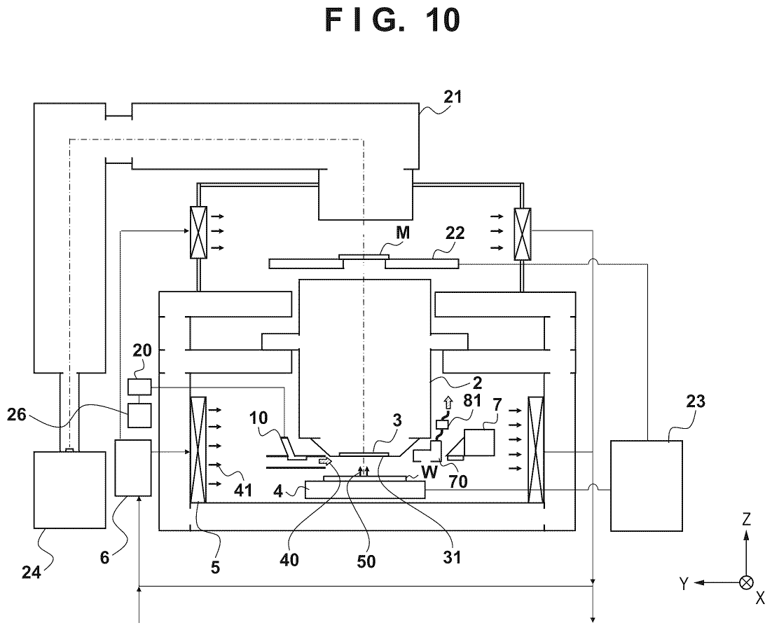

The first gas 40 can be supplied from an air conditioning unit 26 shown in FIG. 10 (to be described later). Note that the air conditioning unit 26 is sometimes placed in the exposure apparatus and is other times placed outside the exposure apparatus. The air conditioning unit 26 includes a thermal regulator that can regulate the temperature of the first gas 40, and the temperature of the first gas 40 is set to coincide with the ambient (air) temperature between the projection optical system 2 and the substrate stage 4. Alternatively, the temperature of the first gas 40 may be set to be slightly higher than the ambient (air) temperature between the projection optical system 2 and the substrate stage 4 in consideration that the temperature of the first gas 40 is reduced by the piping through which it passes before reaching the space between the projection optical system 2 and the substrate stage 4. In the space where the gas supply unit 10 is placed, an air conditioner 5 is placed to supply a second gas 41 in addition to the first gas 40 supplied by the gas supply unit 10. At least part of the second gas 41 flows so as to pass between the optical element 3 and the substrate stage 4.

The room housing the exposure apparatus 100 is also provided with the air conditioner 5. The second gas 41 blown out from the air conditioner 5 is set to a clean state by a chemical filter 6 placed in the air conditioner 5. The clean state concerning the second gas 41 indicates a state in which impurities such as acids, bases, or organics are kept low by the chemical filter 6. However, the chemical filter 6 deteriorates over time due to long-term use and hence cannot semi-permanently keep the second gas 41 in the clean state. In addition, in a case where the source of the second gas 41 in the air conditioner 5 is air in the clean room housing the exposure apparatus 100, even though the second gas 41 passes through the chemical filter 6, the cleanliness of the second gas 41 is dependent on the cleanliness of the clean room. Furthermore, as the cleanliness of the clean room decreases, the deterioration rate of the chemical filter 6 sometimes increases.

By the time the second gas 41 passes between the optical element 3 and the substrate stage 4, impurities may mix in with the second gas 41. Impurities can be, for example, acids, bases, and organics generated from the adhesive or grease used for actuators, guides, bearings, and the like for driving the substrate stage 4. Alternatively, impurities can be acids, bases, and organics generated from resins, rubbers, and the like used for structures, mounted parts, and the like. Accordingly, it is also difficult from this point of view to maintain the second gas 41 in a clean state. In addition, in a case where a gas in a space where the gas supply unit 10 is placed is circulated and passed through the chemical filter 6 to become the second gas 41, the deterioration rate of the chemical filter 6 may be further increased upon being affected by a contaminant 50 generated from the resist of the substrate W.

As described above, because it is difficult to keep the second gas 41 in a clean state, one of the roles of the gas supply unit 10 is to prevent the second gas 41 from reaching the optical element 3.

The next description is about a case where the exposure apparatus 100 irradiates the substrate W with laser light passing through the projection optical system 2 (that is, exposes the substrate W to light). In a case where the substrate W is irradiated with laser light, the contaminant 50 is generated from the substrate W coated with a resist. The contaminant 50 is an impurity such as an acid, base, or organic. The contaminant 50 includes a component that is generated with a speed in the vertical direction. This component reaches the optical element 3 after moving through the second gas 41 and fogs the optical element 3. Another role of the gas supply unit 10 is to prevent this fogging caused by a component of the contaminant 50. For this purpose, the gas supply unit 10 blows out the first gas 40 to prevent the contaminant 50 from reaching the optical element 3.

As described above, factors that fog the optical element 3 can be roughly classified into two groups. One group includes factors originating from the contaminant 50, which come from immediately below the optical element 3. The other group includes contaminants (impurities) other than the contaminant 50, which are carried by the second gas 41 and come from the surroundings of the optical element 3.

In such a situation, the flow velocity of the first gas 40 supplied from the gas supply unit 10 is generally set to be higher than that of the second gas 41 so as to blow away the contaminant 50. This is because the degree of progression of fogging of the optical element 3 due to the contaminant 50 tends to be higher than that due to the second gas 41. In a case where the flow rate regulator 20 regulates the first gas 40 such that it has a high flow velocity, an airflow immediately below the measurement unit 7 located downstream in the airflow direction, that is, an airflow in a region through which measurement light from the measurement unit 7 passes also has a high flow velocity.

As the airflow in the region through which measurement light from the measurement unit 7 passes has a high flow velocity, turbulent flow tends to occur, which tends to convolute surrounding air, resulting in difficulty maintaining constant temperature, pressure, and humidity. That is, it is difficult to maintain the high measurement accuracy of the measurement unit 7. In addition, increasing the flow velocity of an airflow in this region can cause vibration of the structure of the measurement unit 7 itself. For example, the structure of the measurement unit 7 itself may vibrate in the following cases:
(a) a case where the measurement unit 7 itself is susceptible to external force and tends to vibrate;
(b) a case where the lower surface of the measurement unit 7 is provided with a thin cover, which is vibrated by an airflow; and
(c) a case where the structure of the measurement unit 7 has a projection, against which the first gas 40 strikes to cause vibration.

If the structure of the measurement unit 7 itself vibrates in this manner, measurement light also vibrates. As a result, the measurement unit 7 can have difficulty obtaining an accurate measurement.

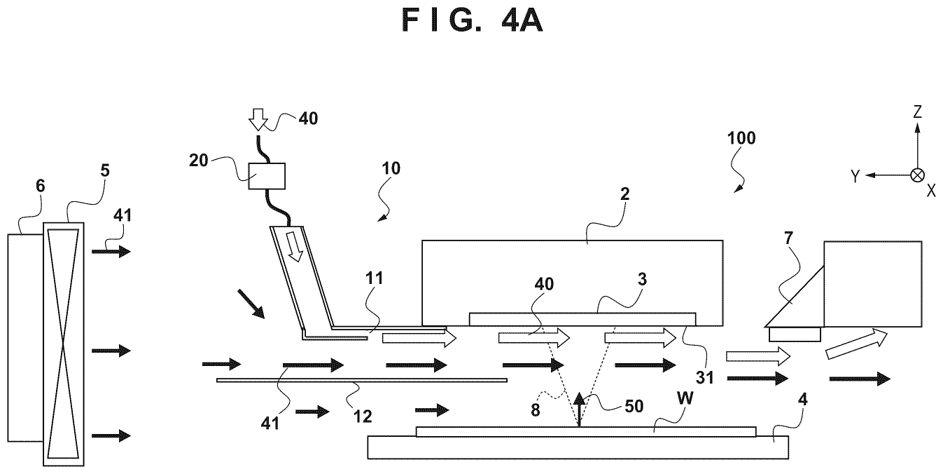

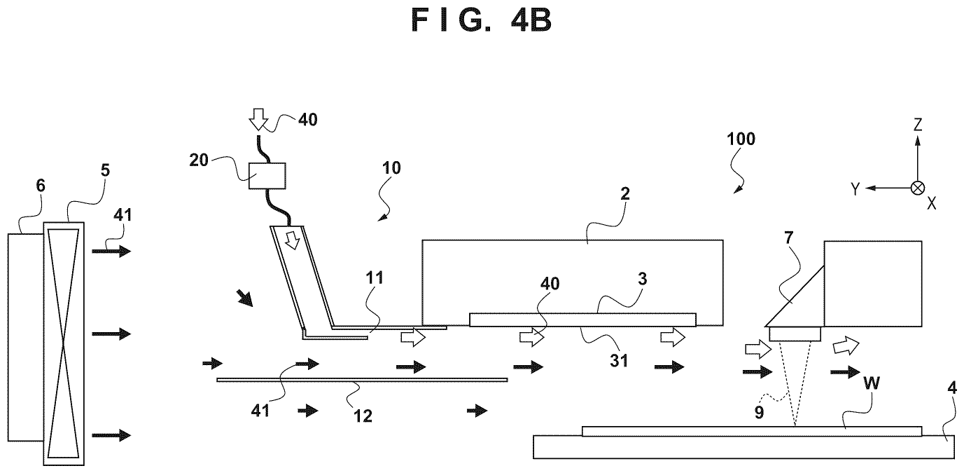

In this embodiment, in order to maintain accurate measurements by the measurement unit 7, the flow rate of the first gas 40 is regulated based on the position of the substrate stage 4 and an exposure sequence. The following is a rough procedure of exposure sequences in the present embodiment:
(a) Wafer loading: taking out the substrate W from a substrate storage unit and loading the substrate W onto the substrate stage 4;
(b) Focus adjustment and reference position adjustment: performing focus adjustment by controlling the Z position of the substrate stage 4 below the projection optical system 2 and then determining a correction value for a reference position (baseline) representing the distance between the projection optical system 2 and the measurement unit 7;
(c) Measurement: emitting measurement light 9 from the measurement unit 7, moving the substrate stage 4 to below the measurement unit 7, and measuring the reference position of the substrate stage 4 and each reference position of the substrate W (at this time, the positional relationship shown in FIG. 4B is established);
(d) Exposure: emitting exposure light from the projection optical system 2 and exposing the substrate W to the exposure light while scanning/moving the substrate stage 4 below the projection optical system 2 (at this time, the positional relationship shown in FIG. 4A is established); and
(e) Wafer unloading: unloading the substrate W from the substrate stage 4 and returning the substrate W to the substrate storage unit. Upon completion of the sequence up to (e), the processing is repeated from (a). Sequences (a) to (e) each may be individually performed. For example, sequence (c) (measurement) is sometimes performed alone.

In order to improve the measurement accuracy of the measurement unit 7, the flow rate regulator 20 regulates the gas flow rate so as to satisfy, for example, the following two conditions:
(1) the flow rate (first flow rate) of the first gas 40 supplied from the gas supply unit 10 during sequence (d) (exposure) should be equal to or greater than the flow rate during another sequence; and
(2) The flow rate (first flow rate) of the first gas 40 supplied from the gas supply unit 10 during sequence (d) (exposure) should be greater than the flow rate (second flow rate) of the first gas 40 supplied from the gas supply unit 10 during sequence (c) (measurement).

In addition, the flow rate (first flow rate) of the first gas 40 supplied from the gas supply unit 10 during sequence (d) (exposure) is advantageous when the flow rate is greater than that of the second gas 41. Accordingly, the controller 23 controls the supply of a gas by the gas supply unit 10 such that the flow velocity of the first gas 40 is greater than that of the second gas 41 supplied from the air conditioner 5.

Furthermore, the flow rate (first flow rate) of the first gas 40 supplied from the gas supply unit 10 during sequence (d) (exposure) is preferably set such that the flow velocity of the first gas 40 is equal to or greater than the moving speed at which the substrate stage 4 scans/moves during exposure. Accordingly, the controller 23 controls the supply of a gas by the gas supply unit 10 such that the flow velocity of the first gas 40 is greater than the scanning speed of the substrate stage 4. This is because it is necessary to blow away the contaminant 50 during scanning/moving of the substrate stage 4, and the above control prevents influence of the movement of the substrate stage 4 on the operation of blowing away the contaminant 50.

The flow rate of the first gas 40 during sequence (c) (measurement) is preferably set to generate a flow velocity almost equal to the flow velocity of the second gas 41 in addition to being less than the flow rate of the first gas 40 during sequence (d) (exposure). Being almost equal to the flow velocity means that the set flow rate generates a flow velocity difference that results in a flow close to a laminar flow instead of disturbing an airflow that results in a turbulent flow due to the flow velocity difference between the first gas 40 and the second gas 41. This flow need not be a perfect laminar flow. For example, in a case where the flow velocity of the second gas 41 is 1 m/s to 2 m/s, the flow velocity of the first gas 40 in a region below the measurement unit 7 is preferably set to be about 0 m/s to 3 m/s. Generating a flow close to a laminar flow makes it difficult to cause convolution and mixing of air from an ambient atmosphere and hence can produce an atmosphere with less air fluctuation, that is, with stable temperature, pressure, and humidity. This makes it possible to obtain high measurement accuracy by the measurement unit 7. Generating a weak flow close to a laminar flow will add only a weak force to the structure of the measurement unit 7 and hence makes it less likely to add a strong force, impact, or unintentional vector to the structure due to a turbulent flow. This is advantageous for the measurement unit 7 concerning vibration.

In sequences other than sequence (d) (exposure) and sequence (c) during which the measurement unit 7 performs measurement, that is, in sequences (a), (b), and (e), the flow rate may be regulated within the range between the first flow rate and the second flow rate. In a case where sequence (c) (measurement) is executed singly, the flow rate set by the flow rate regulator 20 in this interval may be set to the second flow rate.

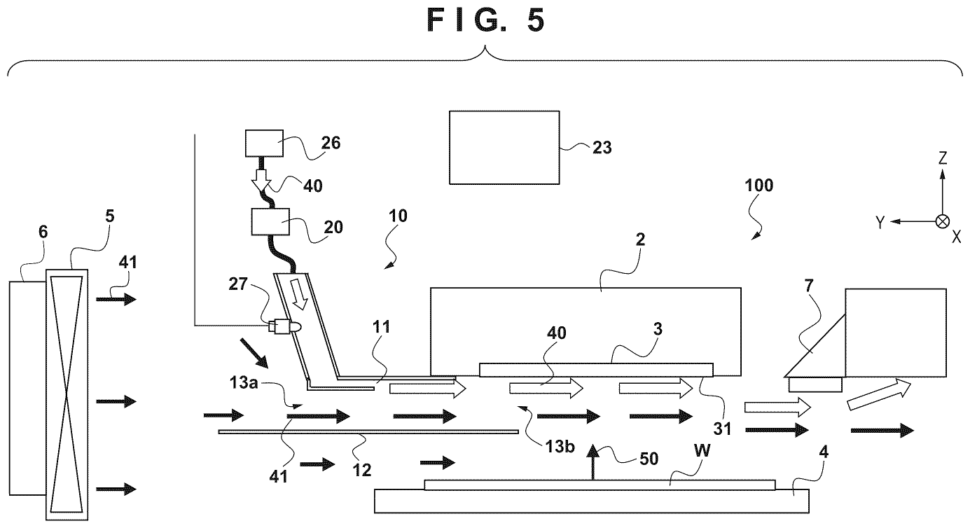

The next description is about a preferable timing of regulation of the first gas 40 by the flow rate regulator 20. In a case where the substrate stage 4 shifts from sequence (c) (measurement) to sequence (d) (exposure), it is preferable that regulation by the flow rate regulator 20 is completed to implement flow rate switching within the movement time of the substrate stage 4. In this switching operation, it is preferable that the flow rate is gradually changed. That is, the controller 23 controls the flow rate regulator 20 to, for example, make continuous or stepwise transition between the first flow rate and the second flow rate. Note, however, that in this switching operation, the flow rate may be rapidly changed. Switching is preferably performed such that the flow rate is regulated to the first flow rate before the substrate stage 4 reaches the exposure start position and is switched to the second flow rate before the substrate stage 4 reaches the measurement start position. Even if flow rate switching is delayed, however, measurement accuracy can still be maintained and preventing the contaminant 50 from reaching the optical element 3 can still be achieved. In addition, if the temperature of the first gas 40 changes due to a large change in its flow rate, the temperature adjustment value of the air conditioning unit 26 may be changed in accordance with the change in flow rate. For example, the temperature of the first gas 40 when it reaches below the projection optical system 2 is adjusted to be constant in the case of the first flow rate and in the case of the second flow rate. If it is difficult to predict a change in temperature, a temperature sensor 27 may be placed at the gas supply unit 10 as shown in FIG. 5 to perform temperature adjustment by the air conditioning unit 26 in accordance with the measurement result obtained by the temperature sensor 27.

In addition, in a case where the substrate stage 4 shifts from sequence (b) (focus adjustment and reference position adjustment) to sequence (c) (measurement), it is preferable that regulation by the flow rate regulator 20 is completed to implement flow rate switching within the movement time of the substrate stage 4.

### Second Embodiment

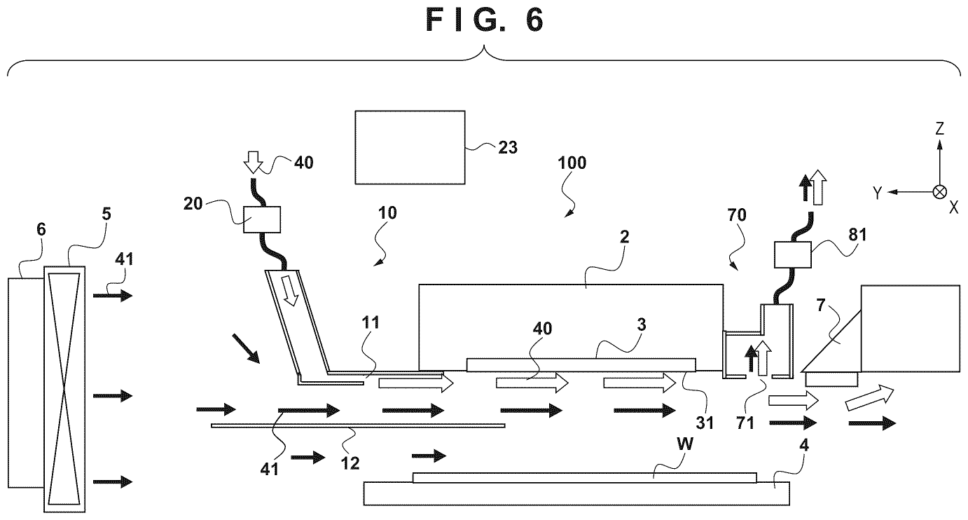

An exposure apparatus 100 according to a second embodiment will be described with reference to FIG. 6. The same reference numerals as in the first embodiment denote the same constituent elements in the second embodiment, and a description will not be repeated. Matters that are not particularly referred to in the following description comply with the above description of the first embodiment.

Referring to FIG. 6, the exposure apparatus 100 further includes an exhaust unit 70 and an exhaust flow rate regulator 81. The exhaust unit 70 has an exhaust port 71 that performs gas exhaustion from the space between an optical element 3 and a measurement unit 7. In the second embodiment, as in the first embodiment, a flow rate regulator 20 regulates the flow rate of a first gas 40. In accordance with this regulation, an exhaust flow rate regulator 81 regulates the exhaust flow rate.

The exhaust unit 70 has a function of straightening the fast flow of the first gas 40 as well as having a function of exhausting a contaminant 50 blown away by the first gas 40 flowing from a gas supply unit 10. Accordingly, the exhaust unit 70 is placed downstream of the gas supply unit 10, as shown in FIG. 6. The exhaust unit 70 is preferably placed between the optical element 3 and the measurement unit 7 for the following three reasons.

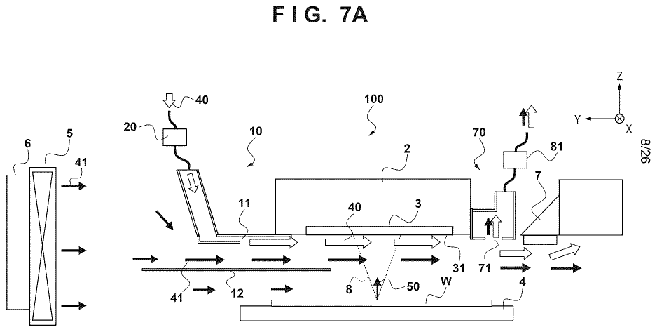

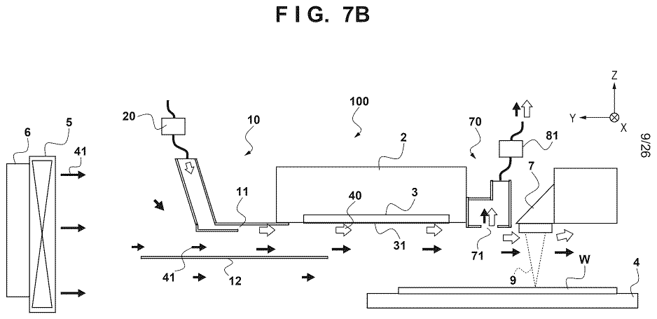

The first reason is to reduce the amount of the contaminant 50 reaching the measurement unit 7. As shown in FIG. 7A, if the exhaust unit 70 is placed between the optical element 3 and the measurement unit 7, the contaminant 50 blown away by the first gas 40 is partially sucked up by the exhaust port 71, and hence the amount of the first gas 40, and thus, contaminant 50, reaching the measurement unit 7 decreases.

The second reason is to improve the fogging prevention function with respect to the optical element 3. In a case where the substrate stage 4 moves to below the measurement unit 7, the flow rate regulator 20 sets the flow rate of the first gas 40 to the second flow rate to reduce the flow velocity, thus reducing the force for blowing away the contaminant 50. However, in a case where the exhaust unit 70 is placed as shown in FIG. 7B, even if the contaminant 50 remains on the substrate W because it is not blown away by the first gas 40, the contaminant 50 is sucked up by the exhaust unit 70, and the amount of the contaminant 50 reaching the optical element 3 decreases.

The third reason is to suck up the first gas 40 before it reaches the space below the measurement unit 7. This makes it possible to more easily reduce the flow of the first gas 40 and reduce the flow rate regulation width of the first gas 40 more than in the first embodiment.

The preferable exhaust flow rate regulation value of the exhaust unit 70 will be described next. The exhaust flow rate regulation value is preferably 50% or more of the flow rate regulation value of the first gas 40 and is more preferably equal to or greater than the flow rate regulation value of the first gas 40. Such setting is necessary to straighten the fast flow of the first gas 40. As the flow rate regulation value of the first gas 40 increases, because the space between the optical element 3 and the substrate W is narrow, the flow sometimes becomes clogged. In order to reduce this clogging of the flow, the exhaust flow rate regulation value can be set to the magnitude associated with the flow rate regulation value of the first gas 40. In addition, in order to reduce the clogging of the flow, in a case where the first gas 40 is regulated to the first flow rate, it is preferable that the regulation of the exhaust flow rate is completed before the completion of regulation to the first flow rate. However, this is not essential.

### Third Embodiment

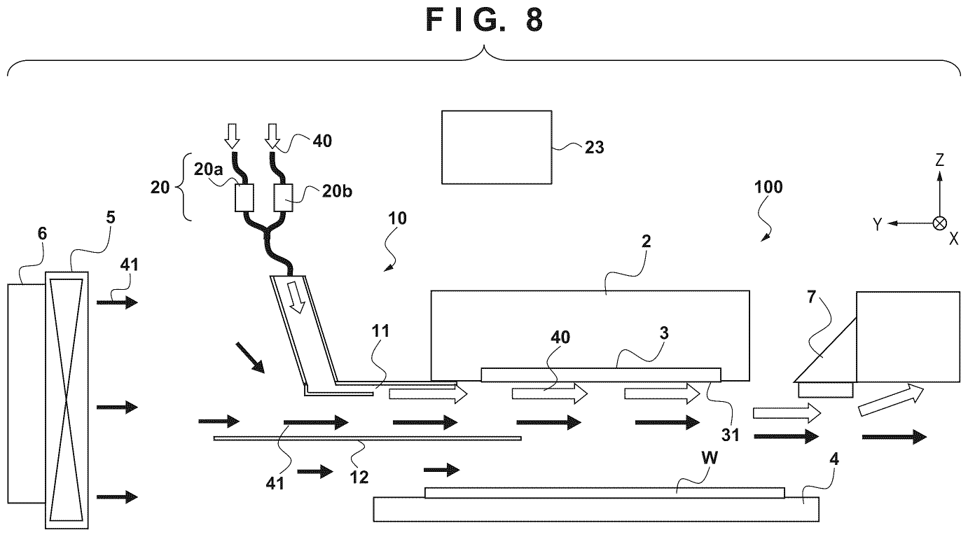

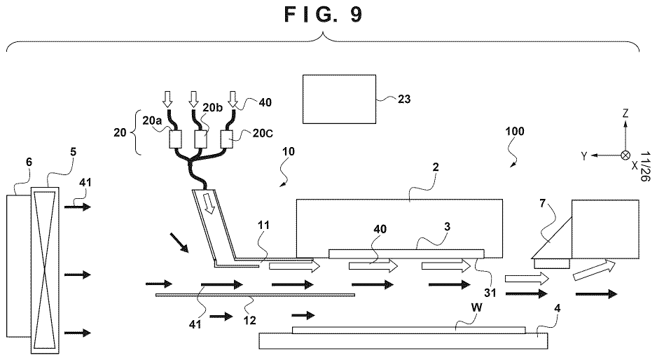

An exposure apparatus 100 according to a third embodiment will be described with reference to FIGS. 8 and 9. The same reference numerals as in the first and second embodiments denote the same constituent elements in the third embodiment, and a description will not be repeated. Matters that are not particularly referred to in the following description comply with the above description of the first and second embodiments.

In the third embodiment, a flow rate regulator 20 includes flow rate regulators of a plurality of systems. Although FIGS. 8 and 9 do not illustrate the exhaust unit 70 and the exhaust flow rate regulator 81 described in the second embodiment, they may be arranged in the apparatus.

In the example shown in FIG. 8, the flow rate regulator 20 can include a first flow rate regulator 20a and a second flow rate regulator 20b. For example, the first flow rate regulator 20a sets the gas flow rate to the first flow rate, and the second flow rate regulator 20b sets the gas flow rate to the second flow rate. The first flow rate regulator 20a and the second flow rate regulator 20b each can switch ON or OFF to control gas output (under the control of a controller 23 (to be described later)). Alternatively, the second flow rate regulator 20b causes a gas to always flow at the second flow rate, and the first flow rate regulator 20a sets a gas flow rate such that the total flow rate of a gas from the first flow rate regulator 20a and a gas from the second flow rate regulator 20b becomes the first flow rate. The first flow rate regulator 20a can switch ON or OFF to control gas output (under the control of the controller 23).

In the example shown in FIG. 9, the flow rate regulator 20 can include the first flow rate regulator 20a, the second flow rate regulator 20b, and a third flow rate regulator 20c. The first flow rate regulator 20a, the second flow rate regulator 20b, and the third flow rate regulator 20c each of which can control the total gas flow rate by switching ON or OFF to control gas output. For example, the second flow rate regulator 20b and the third flow rate regulator 20c each set a gas flow rate so as to make the total flow rate of gases from both the regulators become the second flow rate. The first flow rate regulator 20a sets a gas flow rate such that the total flow rate of gases from the first flow rate regulator 20a, the second flow rate regulator 20b, and the third flow rate regulator 20c becomes the first flow rate. The first flow rate regulator 20a, the second flow rate regulator 20b, and the third flow rate regulator 20c each can switch ON or OFF to control gas output (under the control of the controller 23). In this manner, the regulation resolution of a gas flow rate can be improved in accordance with the number of flow rate regulation systems in the flow rate regulator 20, thereby implementing various gas flow rates.

### Fourth Embodiment

An embodiment of an exposure apparatus will be described as a fourth embodiment. FIG. 10 shows the overall arrangement of an exposure apparatus 100 according to the fourth embodiment. The exposure apparatus 100 can include an illumination optical system 21, an original plate stage 22, a projection optical system 2, a substrate stage 4, and a controller 23. The illumination optical system 21 illuminates an original plate M held by the original plate stage 22 by using light from a light source 24 (for example, a laser light source). The projection optical system 2 projects a pattern image from the original plate M onto a substrate W held by the substrate stage 4. With this operation, the pattern is transferred onto the resist applied on the substrate W. The substrate stage 4 and the original plate stage 22 scan/move upon receiving a command from the controller 23.

An air conditioning unit 26 includes a piping component for supplying a first gas 40 to a gas supply unit 10 through a flow rate regulator 20 and, for example, supplies clean air or nitrogen gas to the gas supply unit 10. The air conditioner 5 supplies a second gas 41 to the space where the gas supply unit 10 is placed. Since the source of the second gas 41 is sometimes air in a clean room, it is difficult to maintain the second gas 41 in a perfectly clean state. In addition, the space in which the gas supply unit 10 is placed includes a driving system and a structure for the substrate stage 4, which further include components that use grease, adhesive, resin, rubber, and the like which are likely to generate contaminants. It is therefore difficult to maintain a perfectly clean state.

As described above in the first to third embodiments, the gas supply unit 10 is placed at or near the projection optical system 2 and supplies the first gas 40 to the space between the optical element 3 at the lowermost end of the projection optical system 2 and the substrate stage 4. The gas supply unit 10 supplies the first gas 40 to protect the optical element 3 from the contaminant 50 generated from the substrate W and the contaminated second gas 41 while the substrate W is held by the substrate stage 4. This makes it possible to prevent the optical element 3 from being fogged or delay the progression of fogging.

During exposure using the projection optical system 2, the controller 23 controls the flow rate regulator 20 so as to make the flow rate (first flow rate) of the first gas 40 supplied from the gas supply unit 10 become equal to or greater than the flow rate during another sequence. In contrast, during measurement using the measurement unit 7, the controller 23 controls the flow rate regulator 20 so as to make the flow rate (second flow rate) of the first gas 40 supplied from the gas supply unit 10 become less than the flow rate (first flow rate) of the first gas 40 supplied from the gas supply unit 10 during exposure. For example, the controller 23 controls the flow rate regulator 20 so as to make the flow velocity of the first gas 40 supplied from the gas supply unit 10 become almost equal to the flow velocity of the second gas 41 from the air conditioner 5. This makes it possible to maintain high measurement accuracy of the measurement unit 7.

### Fifth Embodiment

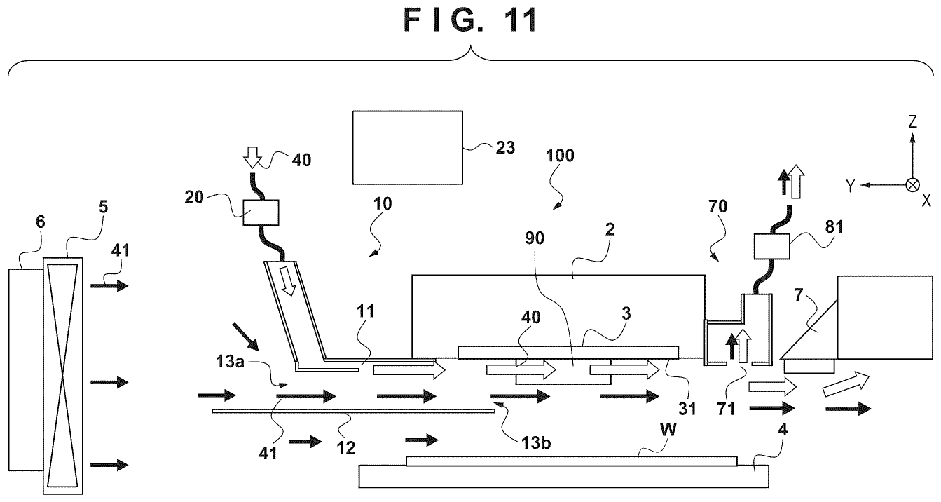

Referring to FIG. 11, an exposure apparatus 100 according to a firth embodiment can include a projection optical system 2, a substrate stage 4, a measurement unit 7, a detector 90, and a controller 23. The projection optical system 2 can include an optical element 3 placed at the lowermost end of the projection optical system 2. The exposure apparatus 100 can further include a gas supply unit 10 (supply unit). The gas supply unit 10 supplies a first gas 40 to the space between the projection optical system 2 (the optical element 3 thereof) and a substrate W (wafer) held by the substrate stage 4. The gas supply unit 10 can include a gas supply port 11 and a flow rate regulator 20 that regulates the supply flow rate of the first gas 40 flowing from the gas supply port 11. The gas supply unit 10 may be fixed to the projection optical system 2 or fixed to a base portion (not shown) near the projection optical system 2.

The measurement unit 7 is configured to emit measurement light to the substrate stage 4 and measure the position of the substrate stage 4 or the substrate W in the X and Y directions. The measurement unit 7 can be, for example, an off-axis alignment scope (OAS) for measuring a mark on a substrate. In order to improve the measurement accuracy of the measurement unit 7, there is a need to maintain constant temperature, pressure, and humidity of an atmosphere through which measurement light passes. The measurement unit 7 is placed at any position where the first gas 40 flows. Referring to FIG. 11, the measurement unit 7 is placed downstream of the projection optical system 2 with respect to the airflow of the first gas 40. However, the measurement unit 7 may be placed upstream of the projection optical system 2.

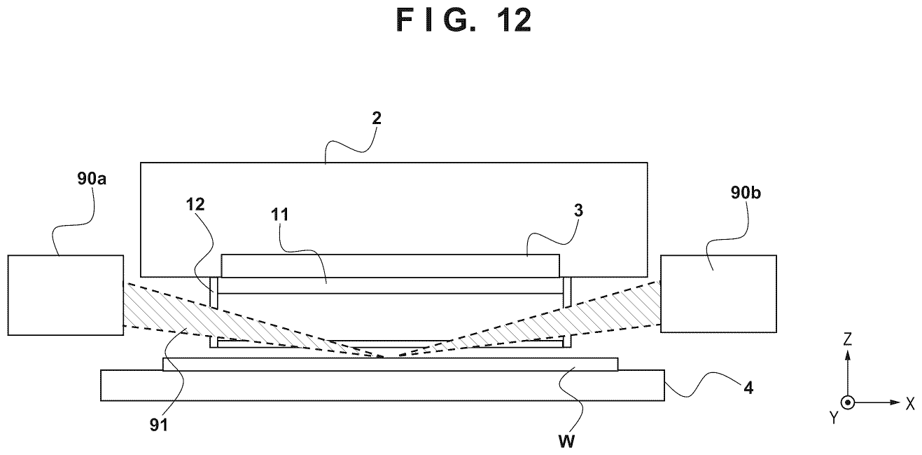

The detector 90 is configured to obliquely apply light to the substrate W and detect the height (Z-direction position) of the substrate W by using the light reflected by the substrate W. More specifically, as shown in FIG. 12, the detector 90 can include a light-emitting unit 90a and a light-receiving unit 90b. The height of the substrate W can be measured by obliquely applying measurement light 91 from the light-emitting unit 90a to the substrate W and receiving the light reflected by the substrate W with the light-receiving unit 90b.

The gas supply unit 10 can further include a baffle plate 12. A first opening portion 13a is formed by a partition of the gas supply port 11 and the baffle plate 12 at a position away from the exposure center. A second opening portion 13b is formed by the projection optical system 2 and the baffle plate 12 at a position close to the exposure center. Although the baffle plate 12 is used to regulate an airflow around the gas supply unit 10 in a predetermined direction, prevent the convolution of a surrounding gas, or regulate the convoluting direction of the surrounding gas, the baffle plate 12 is not essential. As an example of the exposure apparatus 100 without the baffle plate 12, the lower wall of the gas supply port 11 of the gas supply unit 10 may be extended into the space between the optical element 3 and the substrate stage 4 so as to function as a baffle plate. Referring to FIGS. 11 and 12, although the gas supply port 11 is placed to be positioned below the projection optical system 2, the gas supply port 11 may be placed elsewhere relative to the projection optical system 2 and configured to supply the first gas 40 from the placed position to the space between the optical element 3 and the substrate stage 4.

The controller 23 is configured by a computer including, for example, a CPU (processor) and a memory. The controller 23 is electrically connected to each unit in the apparatus to comprehensively control each unit. Note that the controller 23 may be implemented as a server apparatus that is installed in a place different from a room (for example, a clean room) where the exposure apparatus 100 is installed and connected to the exposure apparatus 100 via a wired or wireless network.

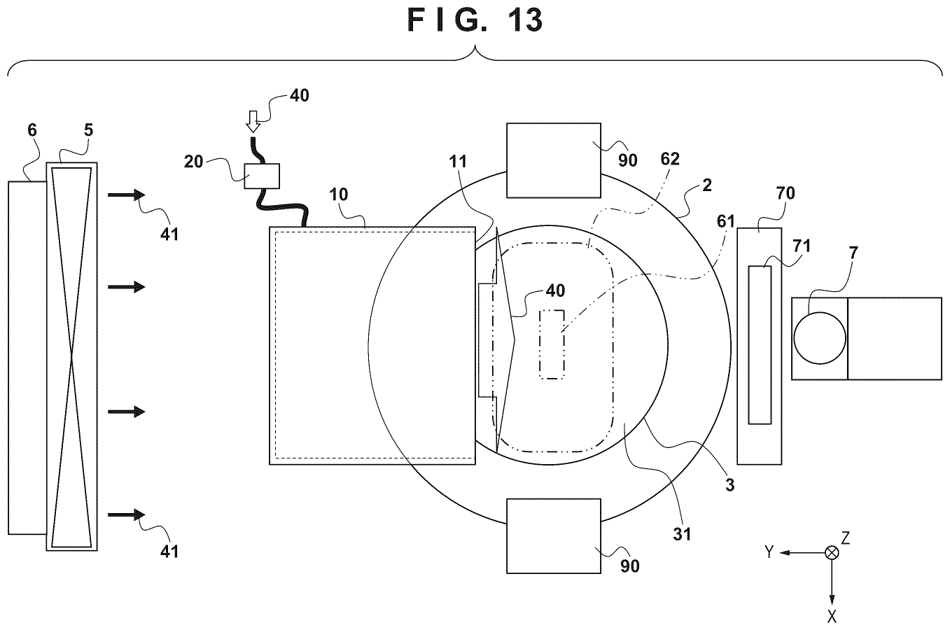

FIG. 13 illustrates a view of the gas supply unit 10 from below the projection optical system 2 (although the baffle plate 12 is not shown). As shown in FIG. 13, the size of the gas supply port 11 in a direction (X direction) perpendicular to the blowing direction (Y direction) of the first gas 40 through the gas supply port 11 is preferably larger than an irradiation range 61 that is a range in which the substrate W is irradiated with laser light passing through the projection optical system 2. Furthermore, the size is preferably larger than a range 62 in which laser light passes through a first surface 31 of the optical element 3, which is located on the side of the optical element 3 facing the substrate W.

The first gas 40 is preferably a clean gas so as not to adversely affect the fogging of the optical element 3. A clean gas means a gas with few impurities such as acids, bases, or organics. This gas is further preferably a gas such as an inert gas like nitrogen gas obtained by drying clean air (clean dry air) obtained by removing impurities such as acids, bases, or organics from air (clean air).

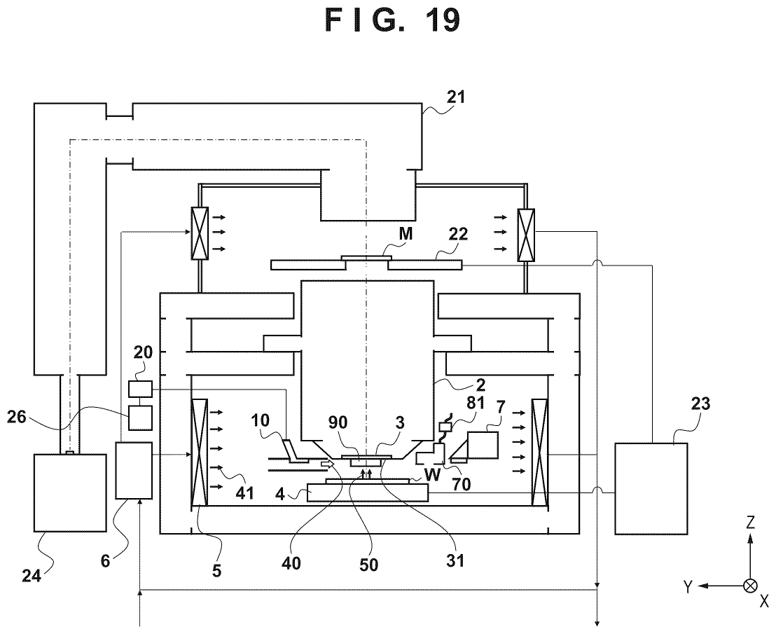

The first gas 40 can be supplied from an air conditioning unit 26 shown in FIG. 19 (to be described later). Note that the air conditioning unit 26 is sometimes placed in the exposure apparatus and is other times placed outside the exposure apparatus. The air conditioning unit 26 includes a thermal regulator that can regulate the temperature of the first gas 40, and the temperature of the first gas 40 is set to coincide with the ambient (air) temperature between the projection optical system 2 and the substrate stage 4. Alternatively, the temperature of the first gas 40 may be set to be slightly higher than the ambient (air) temperature between the projection optical system 2 and the substrate stage 4 in consideration that the temperature of the first gas 40 is reduced by the piping through which it passes before reaching the space between the projection optical system 2 and the substrate stage 4. In the space where the gas supply unit 10 is placed, an air conditioner 5 is placed to supply a second gas 41 in addition to the first gas 40 supplied by the gas supply unit 10. At least part of the second gas 41 flows so as to pass between the optical element 3 and the substrate stage 4.

The room housing the exposure apparatus 100 is also provided with the air conditioner 5. The second gas 41 blown out from the air conditioner 5 is set to a clean state by a chemical filter 6 placed in the air conditioner 5. The clean state concerning the second gas 41 indicates a state in which impurities such as acids, bases, or organics are kept low by the chemical filter 6. However, the chemical filter 6 deteriorates over time due to long-term use and hence cannot semi-permanently keep the second gas 41 in the clean state. In addition, in a case where the source of the second gas 41 in the air conditioner 5 is air in the clean room housing the exposure apparatus 100, even though the second gas 41 passes through the chemical filter 6, the cleanliness of the second gas 41 is dependent on the cleanliness of the clean room. Furthermore, as the cleanliness of the clean room decreases, the deterioration rate of the chemical filter 6 sometimes increases.

By the time the second gas 41 passes between the optical element 3 and the substrate stage 4, impurities may mix in with the second gas 41. Impurities can be, for example, acids, bases, and organics generated from the adhesive or grease used for actuators, guides, bearings, and the like for driving the substrate stage 4. Alternatively, impurities can be acids, bases, and organics generated from resins, rubbers, and the like used for structures, mounted parts, and the like. Accordingly, it is also difficult from this point of view to maintain the second gas 41 in a clean state. In addition, in a case where a gas in a space where the gas supply unit 10 is placed is circulated and passed through the chemical filter 6 to become the second gas 41, the deterioration rate of the chemical filter 6 may be further increased upon being affected by a contaminant 50 generated from the resist of the substrate W.

As described above, because it is difficult to keep the second gas 41 in a clean state, one of the roles of the gas supply unit 10 is to prevent the second gas 41 from reaching the optical element 3.

The next description is about a case where the exposure apparatus 100 irradiates the substrate W with laser light passing through the projection optical system 2 (that is, exposes the substrate W to light). In a case where the substrate W is irradiated with laser light, the contaminant 50 is generated from the substrate W coated with a resist. The contaminant 50 is an impurity such as an acid, base, or organic. The contaminant 50 includes a component that is generated with a speed in the vertical direction. This component reaches the optical element 3 after moving through the second gas 41 and fogs the optical element 3. Another role of the gas supply unit 10 is to prevent this fogging caused by a component of the contaminant 50. For this purpose, the gas supply unit 10 blows out the first gas 40 to prevent the contaminant 50 from reaching the optical element 3.

As described above, factors that fog the optical element 3 can be roughly classified into two groups. One group includes factors originating from the contaminant 50, which come from immediately below the optical element 3. The other group includes contaminants (impurities) other than the contaminant 50, which are carried by the second gas 41 and come from the surroundings of the optical element 3.

In such a situation, the flow velocity of the first gas 40 supplied from the gas supply unit 10 is generally set to be higher than that of the second gas 41 so as to blow away the contaminant 50. This is because the degree of progression of fogging of the optical element 3 due to the contaminant 50 tends to be higher than that due to the second gas 41. In a case where the flow rate regulator 20 regulates the first gas 40 such that it has a high flow velocity, an airflow immediately below the measurement unit 7 located downstream in the airflow direction, that is, an airflow in a region through which measurement light from the measurement unit 7 passes also has a high flow velocity.

As the airflow in the region through which measurement light from the measurement unit 7 passes has a high flow velocity, turbulent flow tends to occur, which tends to convolute surrounding air, resulting in difficulty maintaining constant temperature, pressure, and humidity. That is, it is difficult to maintain the high measurement accuracy of the measurement unit 7. In addition, increasing the flow velocity of an airflow in this region can cause vibration of the structure of the measurement unit 7 itself. For example, the structure of the measurement unit 7 itself may vibrate in the following cases:
(a) a case where the measurement unit 7 itself is susceptible to external force and tends to vibrate;
(b) a case where the lower surface of the measurement unit 7 is provided with a thin cover, which is vibrated by an airflow; and
(c) a case where the structure of the measurement unit 7 has a projection, against which the fast first gas 40 strikes to cause vibration.

If the structure of the measurement unit 7 itself vibrates in this manner, measurement light also vibrates. As a result, the measurement unit 7 can have difficulty obtaining an accurate measurement.

As shown in FIG. 11, the exposure apparatus 100 further includes an exhaust unit 70 and an exhaust flow rate regulator 81. The exhaust unit 70 has an exhaust port 71 that performs gas exhaustion from the space between an optical element 3 and a measurement unit 7. The flow rate regulator 20 regulates the flow rate of the first gas 40. In accordance with this regulation, an exhaust flow rate regulator 81 also regulates the exhaust flow rate.

The exhaust unit 70 has a function of straightening the fast flow of the first gas 40 as well as having a function of sucking up a contaminant 50 blown away by the first gas 40 flowing from a gas supply unit 10. Accordingly, the exhaust unit 70 is placed downstream of the gas supply unit 10, as shown in FIG. 11. The exhaust unit 70 is preferably placed between the optical element 3 and the measurement unit 7 for the following three reasons.

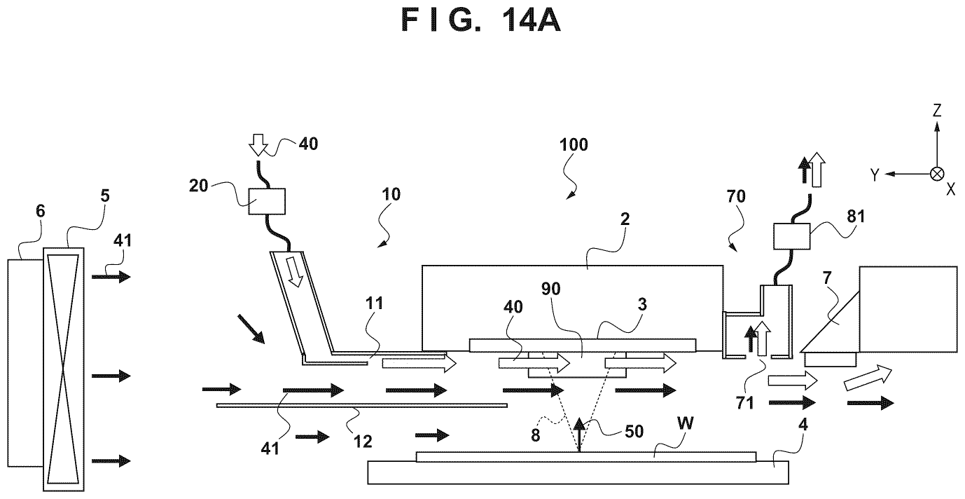

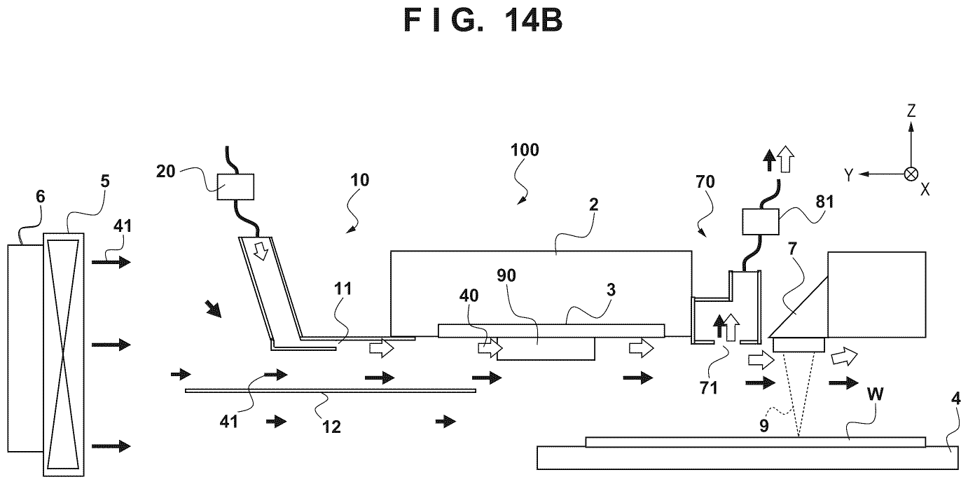

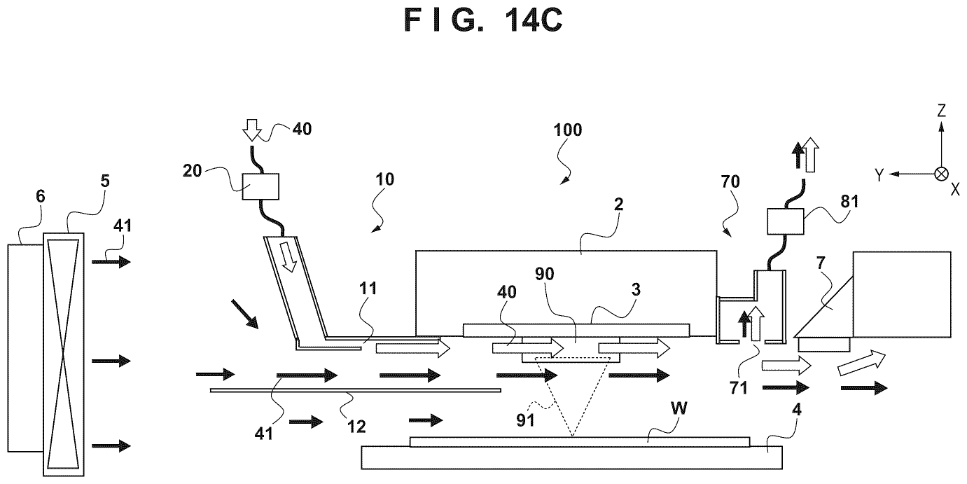

The first reason is to reduce the amount of the contaminant 50 reaching the measurement unit 7. As shown in FIG. 14A, if the exhaust unit 70 is placed between the optical element 3 and the measurement unit 7, the contaminant 50 blown away by the first gas 40 is partially sucked up by the exhaust port 71, and hence the amount of the first gas 40, and thus, contaminant 50, reaching the measurement unit 7 decreases.

The second reason is to improve the fogging prevention function with respect to the optical element 3. In a case where the substrate stage 4 moves to below the measurement unit 7, the flow rate regulator 20 sets the flow rate of the first gas 40 to the second flow rate to reduce the flow velocity, thus reducing the force for blowing away the contaminant 50. However, in a case where the exhaust unit 70 is placed as shown in FIG. 14B, even if the contaminant 50 remains on the substrate W because it is not blown away by the first gas 40, the contaminant 50 is sucked up by the exhaust unit 70, the amount of the contaminant 50 reaching the optical element 3 decreases.

The third reason is to suck up the first gas 40 before it reaches to the space below the measurement unit 7. This makes it possible to more easily reduce the flow of the first gas 40 and reduce the flow rate regulation width of the first gas 40 more than in the first embodiment.

Providing the apparatus with the exhaust unit 70 and the exhaust flow rate regulator 81 is preferable because it aids effective airflow control using the gas supply unit 10. However, it is not essential to include the exhaust unit 70 and the exhaust flow rate regulator 81.

In the present embodiment, in order to maintain accurate measurements by the measurement unit 7, the flow rate of the first gas 40 is regulated based on the position of the substrate stage 4 and an exposure sequence. An exposure sequence (exposure method) according to the present embodiment can include the following steps:
(first step) controlling the supply of a first gas 40 by the gas supply unit 10 so as to make the flow velocity of the first gas 40 passing between the measurement unit 7 and a substrate become equal to that during an exposure period in the first preparation period in which the height of the substrate is detected by using the detector 90 before the start of exposure; and
(second step) controlling the supply of a first gas 40 by the gas supply unit 10 so as to make the flow velocity of the first gas 40 passing between the measurement unit 7 and the substrate become lower than that during an exposure period in the second preparation period in which measurement is performed by using the measurement unit 7 before the start of exposure after the first preparation period.

The following is a specific procedure of an exposure sequence in the present embodiment:
(a) Wafer loading: loading the substrate W from a substrate storage unit and mounting the substrate W onto the substrate stage 4;
(b) Focus adjustment: performing focus adjustment by controlling the Z position of the substrate stage 4 below the projection optical system 2 (at this time, the positional relationship shown in FIG. 14C is established), and focus adjustment including focus measurement using the detector 90;
(c) Reference position adjustment: determining a correction value for a reference position (baseline) representing the distance between the projection optical system 2 and the measurement unit 7 (at this time, the substrate stage 4 reciprocates between the position shown in FIG. 14A and the position shown in FIG. 14B);
(d) Measurement: emitting the measurement light 9 from the measurement unit 7, moving the substrate stage 4 to below the measurement unit 7, and measuring the reference position of the substrate stage 4 and each reference position of the substrate W (at this time, the positional relationship shown in FIG. 14B is established);
(e) Exposure: emitting exposure light from the projection optical system 2 and exposing the substrate W to the exposure light while scanning/moving the substrate stage 4 below the projection optical system 2 (at this time, the positional relationship shown in FIG. 14A is established); and
(f) Wafer unloading: unloading the substrate W from the substrate stage 4 and returning the substrate W to the substrate storage unit. Upon completion of the sequence up to (f), the processing is repeated from (a). Sequences (a) to (f) each may be individually performed. For example, sequence (d) (measurement) is sometimes performed alone.

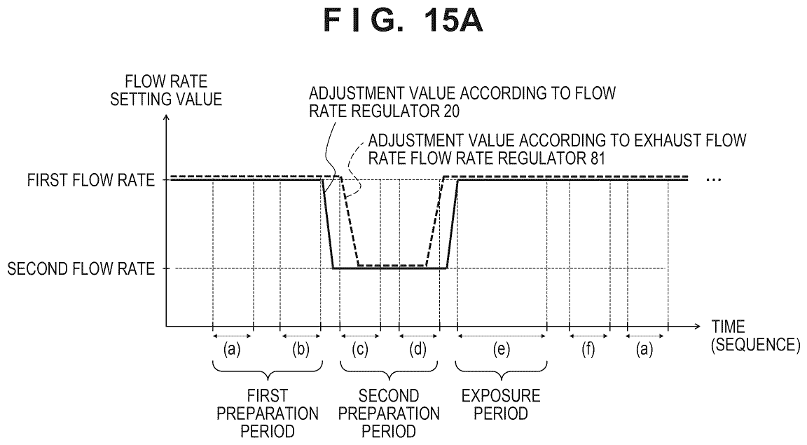

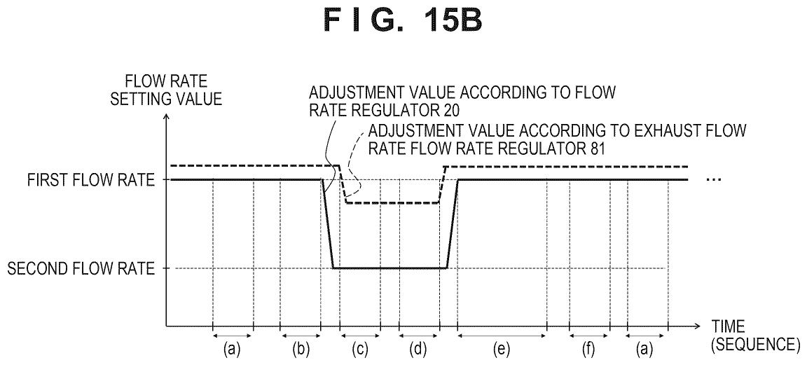

Flow rate regulation performed by the flow rate regulator 20 to improve the measurement accuracy of the measurement unit 7 will be described. FIG. 15A is a timing chart of flow rate regulation of the first gas 40 by the flow rate regulator 20. The abscissa represents the time, along which the above exposure sequence numbers are recorded. The ordinate represents the supply flow rate regulated by the flow rate regulator 20 or the exhaust flow rate regulated by the exhaust flow rate regulator 81. As shown in FIG. 15A, the flow rate is regulated to the first flow rate during a period of operation for sequence (a) (wafer loading) and sequence (b) (focus adjustment) (together, first preparation period). The flow rate is regulated to the second flow rate smaller than the first flow rate during a period of operation for sequence (c) (reference position adjustment) and sequence (d) (measurement) (together, second preparation period). In addition, the flow rate is regulated to the first flow rate during a period of operation for sequence (e) (exposure) (exposure period) and a period of operation for sequence (f) (wafer unloading).

In order to improve the measurement accuracy of the measurement unit 7, the flow rate regulator 20 regulates the gas flow rate so as to satisfy, for example, the following two conditions:
(1) the flow rate (first flow rate) of the first gas 40 supplied from the gas supply unit 10 during sequence (e) (exposure) should be almost equal to the flow rate during another sequence; and
(2) The flow rate (first flow rate) of the first gas 40 supplied from the gas supply unit 10 during sequence (e) (exposure) should be greater than the flow rate (second flow rate) of the first gas 40 supplied from the gas supply unit 10 during sequence (d) (measurement).

In addition, the flow rate (first flow rate) of the first gas 40 supplied from the gas supply unit 10 during sequence (e) (exposure) is advantageous when the flow rate is greater than that of the second gas 41. Accordingly, the controller 23 controls the supply of a gas by the gas supply unit 10 such that the flow velocity of the first gas 40 is greater than that of the second gas 41 supplied from the air conditioner 5.

Furthermore, the flow rate (first flow rate) of the first gas 40 supplied from the gas supply unit 10 during sequence (e) (exposure) is preferably set such that the flow velocity of the first gas 40 is equal to or greater than the moving speed at which the substrate stage 4 scans/moves during exposure. Accordingly, the controller 23 controls the supply of a gas by the gas supply unit 10 such that the flow velocity of the first gas 40 is greater than the scanning speed of the substrate stage 4. This is because it is necessary to blow away the contaminant 50 during scanning/moving of the substrate stage 4, and the above control prevents influence of the movement of the substrate stage 4 on the operation of blowing away the contaminant 50.

The flow rate of the first gas 40 during sequence (d) (measurement) is preferably set to generate a flow velocity almost equal to the flow velocity of the second gas 41 in addition to being less than the flow rate of the first gas 40 during sequence (e) (exposure). Being almost equal to the flow velocity means that the set flow rate generates a flow velocity difference that results in a flow close to a laminar flow instead of disturbing an airflow that results in a turbulent flow due to the flow velocity difference between the first gas 40 and the second gas 41. This flow need not be a perfect laminar flow. For example, in a case where the flow velocity of the second gas 41 is 1 m/s to 2 m/s, the flow velocity of the first gas 40 in a region below the measurement unit 7 is preferably set to be about 0 m/s to 3 m/s. Generating a flow close to a laminar flow makes it difficult to cause convolution and mixing of air from an ambient atmosphere and hence can produce an atmosphere with less air fluctuation, that is, with stable temperature, pressure, and humidity. This makes it possible to obtain high measurement accuracy by the measurement unit 7. Generating a weak flow close to a laminar flow will add only a weak force to the structure of the measurement unit 7 and hence makes it less likely to add a strong force, impact, or unintentional vector to the structure due to a turbulent flow. This is advantageous for the measurement unit 7 concerning vibration.

Sequence (b) (focus adjustment) includes focus measurement performed by using the detector 90 at the same time as during sequence (e) (exposure). For this reason, the flow rate of the first gas 40 is preferably set to the first flow rate so as to set the same condition as that during sequence (e) (exposure). Focus measurement using the detector 90 is also performed during sequence (e) (exposure), and the measured value is used. For this reason, in focus adjustment using the detector 90, the flow rate of the first gas 40 is preferably set to the first flow rate so as to set the same condition as that during exposure. Owing to the structure of the gas supply unit 10, the first gas 40 has little influence on the detector 90 or the measurement light 91, and hence the flow rate of the first gas 40 can be set to the first flow rate without posing any problem.

In sequence (c) (reference position adjustment), the substrate stage 4 reciprocates between the position shown in FIG. 14A and the position shown in FIG. 14B. In this case, although the flow rate of the first gas 40 may be switched between the first flow rate and the second flow rate, the flow rate is preferably fixed to the second flow rate. Since the degree of influence of the first gas 40 on the measurement unit 7 is higher than that on the detector 90, the flow rate is preferably set to the second flow rate in consideration of the degree of influence on the measurement unit 7.

In sequences other than sequence (e) (exposure) and sequence (d) during which the measurement unit 7 performs measurement, that is, in sequences (a), (b), (c), and (f), the flow rate may be regulated within the range between the first flow rate and the second flow rate. For example, in sequences (a) to (f) performed in this order, the flow rate is preferably set to the first flow rate in advance in each of sequences (a) and (f), as shown in FIG. 15A. In a case where sequence (b) (focus adjustment) is executed singly, the flow rate set by the flow rate regulator 20 in this interval may be set to the first flow rate. In a case where sequence (d) (measurement) is executed singly, the flow rate set by the flow rate regulator 20 in this interval may be set to the second flow rate.

The next description is about a preferable way to adjust the first gas 40 using the flow rate regulator 20 when switching between the respective sequences. In a case where the substrate stage 4 shifts from sequence (d) (measurement) to sequence (e) (exposure), it is preferable that regulation by the flow rate regulator 20 is completed to implement flow rate switching within the movement time of the substrate stage 4. In this switching operation, it is preferable that the flow rate is gradually changed. That is, the controller 23 controls the flow rate regulator 20 to, for example, make continuous or stepwise transition between the first flow rate and the second flow rate. Note, however, that in this switching operation, the flow rate may be rapidly changed. Switching is preferably performed such that the flow rate is regulated to the first flow rate before the substrate stage 4 reaches the exposure start position and is switched to the second flow rate before the substrate stage 4 reaches the measurement start position. Even if flow rate switching is delayed, however, measurement accuracy can still be maintained and preventing the contaminant 50 from reaching the optical element 3 can still be achieved.

In a case where the substrate stage 4 shifts from sequence (c) (reference position adjustment) to sequence (d) (measurement), it is preferable that regulation by the flow rate regulator 20 is completed to implement flow rate switching within the movement time of the substrate stage 4.

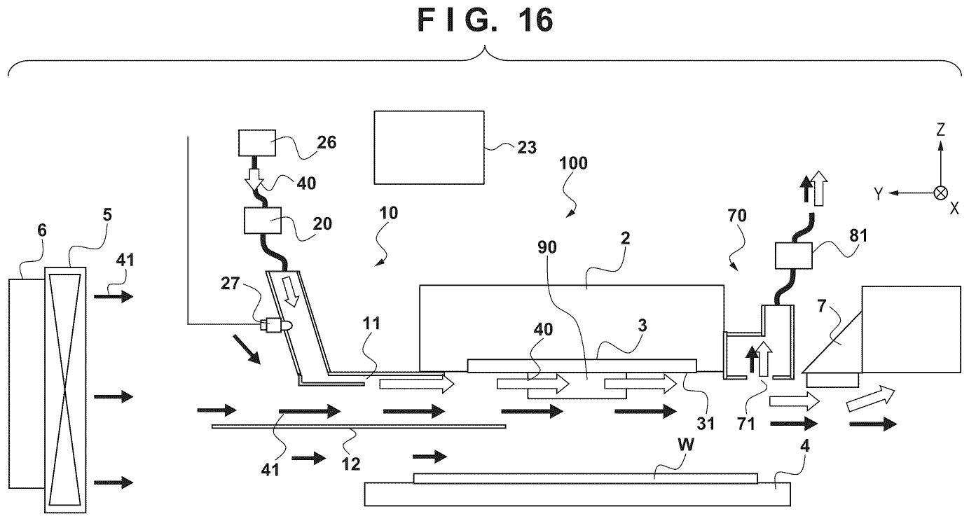

The temperature control of the first gas 40 will be described. The temperature control of the first gas 40 can be important, for example, in a case where the flow rate of the first gas 40 is greatly changed or a case where the first flow rate is high, and the temperature of the first gas 40 blown out from the gas supply port 11 decreases (for example, adiabatic expansion or Joule-Thomson effect). If the temperature of the first gas 40 greatly changes as the flow rate of the first gas 40 is greatly changed, the temperature regulation value of the air conditioning unit 26 may be changed in accordance with the change in flow rate. More specifically, the temperature of the first gas 40 when it reaches below the projection optical system 2 is adjusted to be constant in the case of the first flow rate and in the case of the second flow rate. If it is difficult to predict a change in temperature, a temperature sensor 27 may be placed at the gas supply unit 10 as shown in FIG. 16 to perform temperature adjustment by the air conditioning unit 26 in accordance with the measurement result obtained by the temperature sensor 27. In this manner, the air conditioning unit 26 (temperature controller) performs temperature control so as to keep the temperature of the gas blown out from the gas supply port 11 constant before and after flow rate regulation is performed by the flow rate regulator 20.

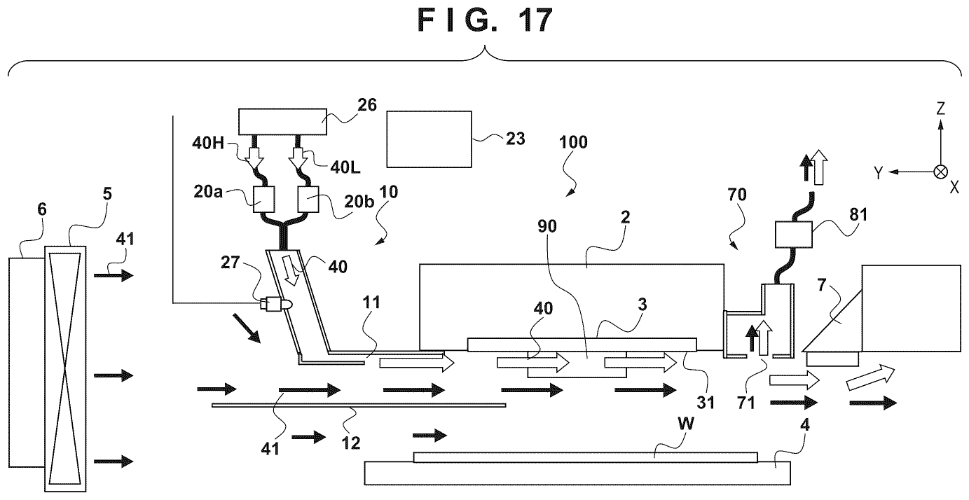

Alternatively, an arrangement like that shown in FIG. 17 may be employed. Referring to FIG. 17, the gas supply unit 10 includes a plurality of flow rate regulators that regulate the flow rate of the first gas 40 blown out from the gas supply port 11, and the controller 23 changes the flow velocity of the first gas 40 passing between the measurement unit 7 and the substrate W by individually controlling the plurality of flow rate regulators. In this case, the controller 23 controls the plurality of flow rate regulators so as to set the flow rate of the first gas 40 blown out from the gas supply port 11 to the first flow rate in the first preparation period (the above period of operation including sequence (a) (wafer loading) and sequence (b) (focus adjustment)) and an exposure period. In addition, the controller 23 controls the plurality of flow rate regulators so as to set the flow rate of the first gas 40 blown out from the gas supply port 11 to the second flow rate less than the first flow rate in the second preparation period (the above period of operation including sequence (c) (reference position adjustment) and sequence (d) (measurement)).

Referring to FIG. 17, the air conditioning unit 26 (temperature controller) is configured to supply gases having different temperatures to the plurality of flow rate regulators. The air conditioning unit 26 supplies, through different systems, a first gas 40H set to a high temperature and a first gas 40L set to a temperature lower than that of the first gas 40H. The flow rate regulator 20 can include a first flow rate regulator 20a that regulates the flow rate of the first gas 40H and a second flow rate regulator 20b that regulates the flow rate of the first gas 40L. The temperature of the first gas 40 may be regulated by generating a gas with the first flow rate or the second flow rate, which is performed by regulating the mixture ratio of the first gas 40H and the first gas 40L based on the temperature measured by the temperature sensor 27. In a case where the temperature of the first gas 40 blown out from the gas supply port 11 decreases due to the Joule-Thomson effect, the temperature upstream of the gas supply port 11 is increased by generating a gas with the first flow rate, which is performed by increasing the mixture ratio of the first gas 40H when setting the first flow rate. At the time of setting the second flow rate, the temperature upstream of the gas supply port 11 is decreased by generating a gas with the second flow rate, which is performed by increasing the mixture ratio of the first gas 40L. Accordingly, the controller 23 regulates the mixture ratio of gases from a plurality of flow rate regulators to keep the temperature of the gas mixture constant before and after the regulation of the flow rate of each of gases from a plurality of flow rate regulators.

This arrangement can perform flow rate regulation at an arbitrary temperature in each of sequences (a) to (f). In each sequence, both an optimal flow rate and an optimal temperature can be set, and hence more accurate measurement can be implemented. Although FIG. 17 shows an example of flow rate regulators of two systems, flow rate regulators of three or more systems may be provided.

A preferable exhaust flow rate regulation value of the exhaust unit 70 will be described next. Referring to FIG. 15B, the broken line indicates an example of a preferable exhaust flow rate regulation value. The exhaust flow rate regulation value is preferably 50% or more of the flow rate regulation value of the first gas 40 and is more preferably equal to or greater than the flow rate regulation value of the first gas 40. Such setting is necessary to straighten the fast flow of the first gas 40. As the flow rate regulation value of the first gas 40 increases, because the space between the optical element 3 and the substrate W is narrow, the flow sometimes becomes clogged. In order to reduce this clogging of the flow, the exhaust flow rate regulation value can be set to the magnitude associated with the flow rate regulation value of the first gas 40. In addition, in order to reduce the clogging of the flow, in a case where the first gas 40 is regulated to the first flow rate, it is preferable that the regulation of the exhaust flow rate is completed before the completion of regulation to the first flow rate. However, this is not essential. In contrast, in a case where the first gas 40 is regulated to the second flow rate, it is preferable that the exhaust flow rate regulation value is delayed and regulated. Note, however, that this is also not essential.

### Sixth Embodiment

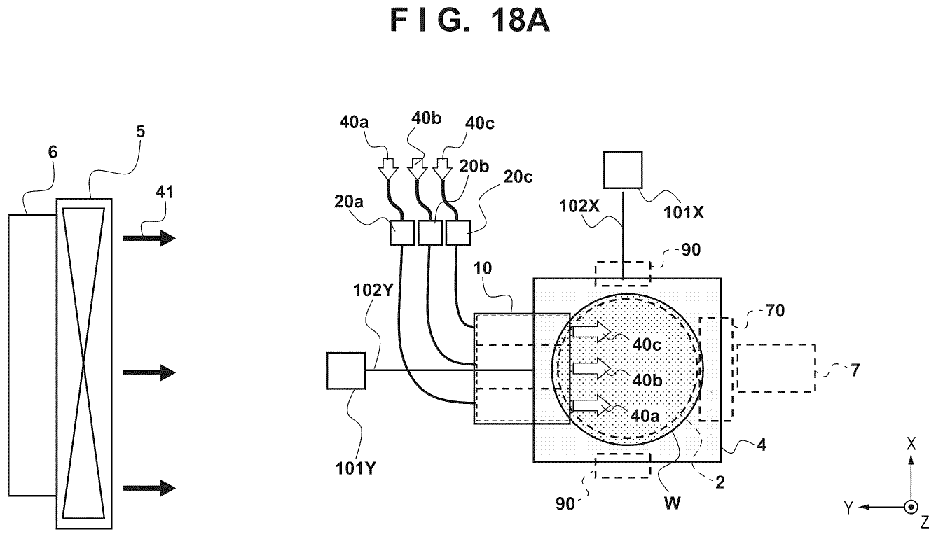

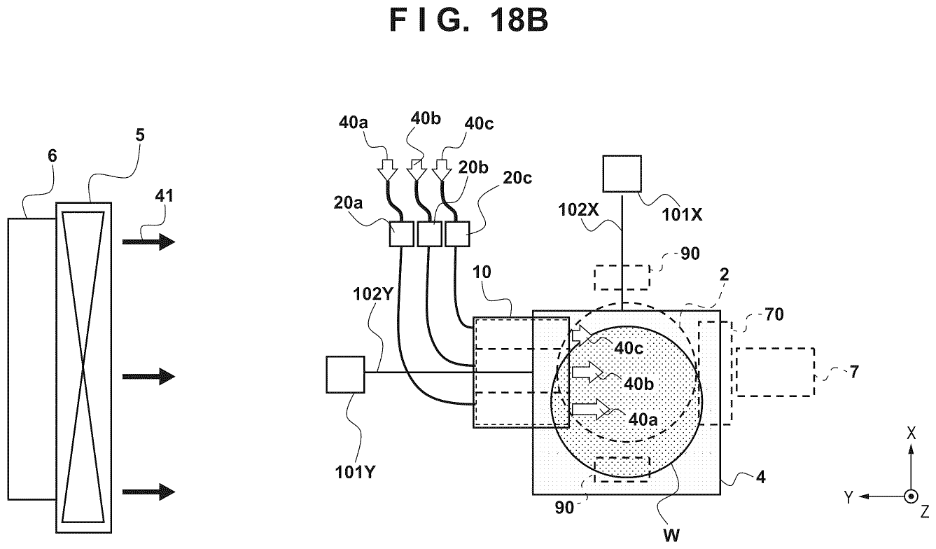

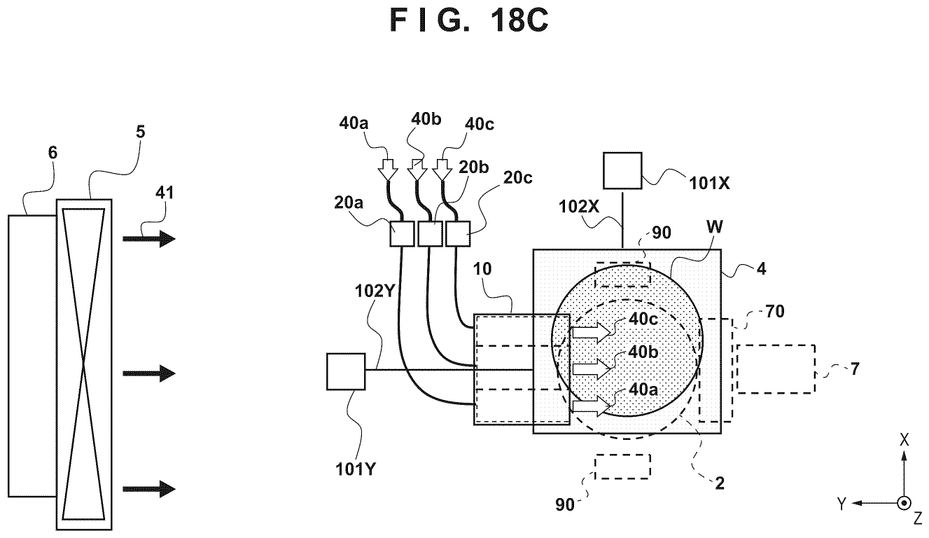

An exposure apparatus according to a sixth embodiment will be described with reference to FIGS. 18A to 18C. The same reference numerals as in the fifth embodiment denote the same constituent elements in the sixth embodiment, and a description will not be repeated. Matters that are not particularly referred to in the following description comply with the above description of the fifth embodiment.

In the sixth embodiment, a controller 23 individually controls a plurality of flow rate regulators so as to form a flow rate distribution corresponding to the distance between a measurement unit (for example, an X measurement unit 101X (to be described later)) and a substrate stage 4. FIG. 18A illustrates a plan view of the substrate stage 4. A flow rate regulator 20 can include a plurality of flow rate regulators 20a, 20b, and 20c. Controlling each of the plurality of flow rate regulators 20a, 20b, and 20c makes it possible to make the first gas 40 from the gas supply unit 10 have a flow rate distribution in the X direction. An exposure apparatus 100 further includes the X measurement unit 101X that measures the position of the substrate stage 4 in the X direction and a Y measurement unit 101Y that measures the position of the substrate stage 4 in the Y direction. The X measurement unit 101X and the Y measurement unit 101Y respectively emit measurement light 102X and measurement light 102Y to measure the position of the substrate stage 4.

FIG. 18B shows a state in which the substrate stage 4 has moved farther from the X measurement unit 101X than in the state shown in FIG. 18A. FIG. 18C shows a state in which the substrate stage 4 has moved closer to the X measurement unit 101X than in the state shown in FIG. 18A. In the sixth embodiment, the plurality of flow rate regulators 20a, 20b, and 20c form the flow rate distribution of the first gas in the X direction to perform flow rate regulation corresponding to the position of the substrate stage 4 in the X direction in addition to the flow rate regulation described in the fifth embodiment. More specifically, in the states shown in FIGS. 18A and 18C, the flow rate regulators 20a, 20b, and 20c form the flow rate distribution of the first gas 40 so as to make the flow rates at their respective positions in the X direction equal to each other. Note that the total flow rate of first gases 40a, 40b, and 40c is the first flow rate. As shown in FIG. 18B, in a case where the position of the substrate stage 4 moves away from the X measurement unit 101X, the flow rate regulator 20c regulates the flow rate of the first gas 40c so as to reduce the flow rate of the gas on the X measurement unit 101X side in accordance with the position of the substrate stage 4. In this case, while the substrate stage 4 is located farthest from the X measurement unit 101X, the flow rate regulator 20c preferably regulates the flow velocity of the first gas 40c to make it equal to the flow velocity of the second gas 41. Alternatively, in a case where the distance between the substrate stage 4 and the X measurement unit 101X is 50% or more of the maximum distance, it is preferable to regulate the flow velocity of the first gas 40c to make it equal to the flow velocity of the second gas 41. This reduces the turbulent state of the gas flowing on the X measurement unit 101X side and makes the state of the gas similar to a laminar state with small flow velocity difference, thereby implementing accurate measurement by the X measurement unit 101X.

### Seventh Embodiment

An embodiment of an exposure apparatus will be described as a seventh embodiment. FIG. 19 shows the overall arrangement of an exposure apparatus 100 according to the seventh embodiment. The exposure apparatus 100 can include an illumination optical system 21, an original plate stage 22, a projection optical system 2, a substrate stage 4, and a controller 23. The illumination optical system 21 illuminates an original plate M held by the original plate stage 22 by using light from a light source 24 (for example, a laser light source). The projection optical system 2 projects a pattern image from the original plate M onto a substrate W held by the substrate stage 4. With this operation, the pattern is transferred onto the resist applied on the substrate W. The substrate stage 4 and the original plate stage 22 scan/move upon receiving a command from the controller 23.

An air conditioning unit 26 includes a piping component for supplying a first gas 40 to a gas supply unit 10 through a flow rate regulator 20 and, for example, supplies clean air or nitrogen gas to the gas supply unit 10. The air conditioner 5 supplies a second gas 41 to the space where the gas supply unit 10 is placed. Because the source of the second gas 41 is sometimes air in a clean room, it is difficult to maintain the second gas 41 in a perfectly clean state. In addition, the space in which the gas supply unit 10 is placed includes a driving system and a structure for the substrate stage 4, which further include components that use grease, adhesive, resin, rubber, and the like which are likely to generate contaminants. It is therefore difficult to maintain a perfectly clean state. An exhaust unit 70 is configured to not only exhaust a contaminant 50 but also contribute to the straightening of a fast flow of the first gas 40. The measurement unit 7 measures the position of the substrate stage 4 or the position of the substrate W. A detector 90 is configured to measure the position of the substrate stage 4 or the substrate W in the Z direction.

As described above in the fifth and sixth embodiments, the gas supply unit 10 is placed at or near the projection optical system 2 and supplies the first gas 40 to the space between the optical element 3 at the lowermost end of the projection optical system 2 and the substrate stage 4. The gas supply unit 10 supplies the first gas 40 to protect the optical element 3 from the contaminant 50 generated from the substrate W and the contaminated second gas 41 while the substrate W is held by the substrate stage 4. This makes it possible to prevent the optical element 3 from being fogged or delay the progression of fogging.

In this case, the flow rate regulator 20 regulates the flow rate of the first gas 40 in accordance with an exposure sequence and the position of the substrate stage 4. This makes it possible to obtain an exposure environment and a measurement environment, each of which have both little influence on exposure and little influence on the measurement accuracy of the measurement unit 7 and the detector 90. Likewise, the exhaust flow rate regulator 81 regulates the exhaust flow rate in accordance with an exposure sequence and the position of the substrate stage 4. This makes it possible to support the airflow control of the first gas 40 so as to reduce the influence on exposure and the influence on the measurement accuracy of the measurement unit 7 and the detector 90.

### Embodiment of Article Manufacturing Method

An article manufacturing method according to the present embodiment is suitable for manufacturing an article, for example, a microdevice such as a semiconductor device or an element having a microstructure. The article manufacturing method according to the present embodiment can include a step of forming a latent image pattern onto a substrate coated with a photosensitive agent by using the above-described exposure apparatus and a step of developing the substrate on which the latent image pattern is formed in the preceding step. The article manufacturing method further can include other known steps (oxidation, deposition, vapor deposition, doping, planarization, etching, resist removal, dicing, bonding, packaging, and the like). The article manufacturing method of the present embodiment is more advantageous than the conventional methods in at least one of the performance, quality, productivity, or production cost of the article.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims priority to and the benefit of Japanese Patent Application Nos. 2024-206580, filed Nov. 27, 2024, and 2024-206581, filed Nov. 27, 2024, the entirety of which are incorporated herein by reference.

What is claimed is:

1. An exposure apparatus that exposes a substrate to light, the apparatus comprising:
a projection optical system configured to project a pattern image of an original plate onto the substrate;
a supply unit configured to supply a gas to a space between the projection optical system and the substrate;
a measurement unit configured to measure a position of the substrate; and
a controller configured to control supply of the gas by the supply unit so as to change a flow velocity of the gas passing between the measurement unit and the substrate.

2. The apparatus according to claim 1, wherein the controller controls supply of the gas by the supply unit so as to change the flow velocity of the gas passing between the measurement unit and the substrate in accordance with progression of an exposure sequence.

3. The apparatus according to claim 2, wherein the controller controls supply of the gas by the supply unit so as to cause the flow velocity of the gas passing between the measurement unit and the substrate to become lower than a flow velocity of the gas during an exposure period of the exposure sequence in which the measurement unit performs measurement.

4. The apparatus according to claim 1, wherein the supply unit includes a gas supply port configured to blow out the gas supplied to the space and a plurality of flow rate regulators configured to regulate a flow rate of the gas blown out from the gas supply port, and
the controller changes the flow velocity of the gas passing between the measurement unit and the substrate by individually controlling each of the plurality of flow rate regulators.

5. The apparatus according to claim 4, wherein the controller controls the plurality of flow rate regulators so as to set a flow rate of the gas blown out from the gas supply port to a first flow rate during an exposure period and a second flow rate lower than the first flow rate during a period in which the measurement unit performs measurement.

6. The apparatus according to claim 1, wherein the supply unit includes a gas supply port configured to blow out the gas supplied to the space and a flow rate regulator configured to regulate a flow rate of the gas blown out from the gas supply port, and
the controller changes the flow velocity of the gas passing between the measurement unit and the substrate by controlling the flow rate regulator.

7. The apparatus according to claim 6, wherein the controller controls the flow rate regulator so as to set a flow rate of the gas blown out from the gas supply port to a first flow rate during an exposure period and a second flow rate lower than the first flow rate during a period in which the measurement unit performs measurement.

8. The apparatus according to claim 7, further comprising an exhaust unit configured to exhaust a gas from the space.

9. The apparatus according to claim 8, wherein the exhaust unit includes an exhaust port configured to perform gas exhaustion from the space at a position located downstream of the projection optical system and upstream of the measurement unit with respect to an airflow of the gas supplied from the supply unit, and an exhaust flow rate regulator configured to regulate an exhaust flow rate of the gas exhausted through the exhaust port, and
the controller controls the exhaust flow rate regulator in accordance with the flow rate of the gas blown out from the gas supply port.

10. The apparatus according to claim 9, wherein the controller controls the exhaust flow rate regulator so as to cause the exhaust flow rate of the gas exhausted through the exhaust port to become higher than the flow rate of the gas blown out from the gas supply port.

11. The apparatus according to claim 9, wherein the exhaust flow rate regulator completes regulation of the exhaust flow rate before the flow rate regulator completes regulation to the first flow rate.

12. The apparatus according to claim 7, wherein the controller controls the flow rate regulator so as to cause the flow rate of the gas blown out from the gas supply port to fall within a range between the first flow rate and the second flow rate during an exposure period and a period other than a period in which the measurement unit performs measurement.

13. The apparatus according to claim 7, wherein the controller controls the flow rate regulator so as to cause continuous or stepwise transition between the first flow rate and the second flow rate.

14. The apparatus according to claim 1, wherein the measurement unit is positioned downstream of the projection optical system with respect to an airflow of the gas supplied from the supply unit.

15. The apparatus according to claim 1, wherein the measurement unit is positioned upstream of the projection optical system with respect to an airflow of the gas supplied from the supply unit.

16. The apparatus according to claim 1, wherein the controller controls supply of the gas by the supply unit so as to cause the flow velocity of the gas supplied from the supply unit and passing through the space to become higher than a flow velocity of a second gas supplied from an air conditioner and passing through the space, the air conditioner being configured to perform air conditioning in a room housing the exposure apparatus.

17. The apparatus according to claim 1, further comprising a stage configured to hold and move the substrate,
wherein the controller controls supply of the gas by the supply unit so as to cause the flow velocity of the gas supplied from the supply unit and passing through the space to become higher than a scanning speed of the stage.

18. An exposure apparatus that exposes a substrate to light, the apparatus comprising:
a projection optical system configured to project a pattern image of an original plate onto the substrate;
a supply unit configured to supply a gas to a space between the projection optical system and the substrate;
a measurement unit configured to measure a position of the substrate;
a detector configured to obliquely apply light to the substrate and detect a height of the substrate by using light reflected by the substrate; and
a controller configured to control supply of the gas by the supply unit,
wherein the controller controls supply of the gas by the supply unit so as to cause the flow velocity of the gas passing between the measurement unit and the substrate to become equal to a flow velocity of the gas during an exposure period in a first preparation period in which the detector detects the height of the substrate before a start of exposure and controls supply of the gas by the supply unit so as to cause the flow velocity of the gas passing between the measurement unit and the substrate to become lower than a flow velocity of the gas during an exposure period in a second preparation period in which the measurement unit performs measurement after the first preparation period and before a start of exposure.

19. An article manufacturing method comprising:
exposing a substrate to light by using an exposure apparatus defined in claim 1; and
developing the substrate exposed to light,
wherein an article is manufactured from the substrate having undergone the developing.
